(19) United States
(12) Patent Application Publication
(10) Pub. No.: US 2010/0047953 A1
(43) Pub. Date: Feb. 25, 2010

(54) METHOD FOR PRODUCING WAFER FOR BACKSIDE ILLUMINATION TYPE SOLID IMAGING DEVICE

(75) Inventors: Kazunari KURITA, Minato-ku (JP); Shuichi OMOTE, Minato-ku (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/544,509

(22) Filed: Aug. 20, 2009

(30) Foreign Application Priority Data
Aug. 21, 2008 (JP) 2008-212577

(51) Int. Cl. H01L 21/322

(52) U.S. Cl. 438/58; 257/E21.317

(57) ABSTRACT

In the production of a wafer for backside illumination type solid imaging device having a plurality of pixels inclusive of a photoelectric conversion device and a charge transfer transistor formed at its front surface side and a light receiving surface at its back surface side, an active layer made of a given epitaxial film is formed on a silicon wafer made of a C-containing CZ crystal directly or through an insulating film, and then subjected to a heat treatment to form precipitates containing C and O as a gettering sink at a position just beneath the active layer.

### BACKGROUND OF THE INVENTION

1. Field of the Invention

This invention relates to a silicon substrate, a production method thereof and a device using the substrate, and more particularly to a method for producing a wafer for backside illumination type solid imaging device, which is used in mobile phones, digital video cameras and the like and is capable of suppressing white defects effectively.

2. Description of the Related Art

Recently, a high-performance solid imaging device using a semiconductor is mounted onto a mobile phone, a digital video camera or the like, and hence the performances such as number of pixels and the like are dramatically improved. As the performance to be expected in the usual solid imaging device are high-quality pixels and ability of taking moving images, and further miniaturization is required. In order to take moving images, it is required to combine with a high-speed computing device and a memory device, and hence a CMOS image sensor allowing System on Chip (SoC) easily is used and the downsizing of the CMOS image sensor is developed.

With the downsizing of the CMOS image sensor, however, there is caused a problem that an aperture ratio of a photo diode as a photoelectric conversion device is inevitably reduced to lower a quantum efficiency of the photoelectric conversion device, which makes it difficult to improve S/N ratio of imaging data. Therefore, it is attempted to conduct a method for increasing incident light quantity by inserting an inner lens into a front side of the photoelectric conversion device, or the like. However, the remarkable improvement of S/N ratio can not be realized.

In order to increase the incident light quantity to improve S/N ratio of the image data, therefore, it is attempted to feed the incident light from a backside of the photoelectric conversion device. The greatest merit of the light incidence from the backside of the device lies in a point that restriction due to reflection or diffraction on the surface of the device or the light receiving area of the device is eliminated as compared with the light incidence from the front side. On the other hand, when the light is entered from the backside, the absorption of the light through a silicon wafer as a substrate of the photoelectric conversion device must be suppressed, and hence the thickness of the solid imaging device as a whole is required to be less than 50 μm. As a result, the working and handling of the solid imaging device become difficult, causing a problem of extremely low productivity.

For the purpose of resolving the above technical problems, there are mentioned solid imaging devices as disclosed, for example, in JP-A-2007-13089 and JP-A-2007-59755.

When using the production method of the solid imaging device in JP-A-2007-13089, it is possible to produce a backside illumination type CMOS solid imaging device having a structure that electrodes are taken out from a surface opposite to the illuminated surface relatively simply and easily.

On the other hand, when using the production method of the solid imaging device in JP-A-2007-59755, it is possible to conduct the processing of a thinned solid imaging device with a high accuracy.

In the solid imaging devices of JP-A-2007-13089 and JP-A-2007-59755, however, the gettering ability of the substrate (wafer) is low, so that there are problems that white defects occur and that heavy metal contamination occurs in the production process. Therefore, it is required to solve these problems in order to put the backside illumination type solid imaging device into practical use.

As a production method for solving the above problems, there is mentioned a method of producing a solid imaging apparatus as disclosed, for example, in JP-A-2002-353434, wherein an element such as carbon or the like is introduced into a silicon substrate to form a buried gettering sink layer and silicon is crystal-grown on the front surface of the silicon substrate to form a crystal growth layer and an element such as phosphorus or the like is introduced into the back surface of the silicon substrate to form a solid imaging device in the crystal growth layer and on an upper layer thereof at a temperature lower than a case of forming an external gettering sink layer.

In the production method described in JP-A-2002-353434, however, if the silicon substrate is subjected to a heat treatment after the formation of the buried gettering sink layer, crystal defects formed by the carbon implantation are mitigated to deteriorate the function of the buried gettering sink layer and subsequently there is caused a fear of contaminating with heavy metal(s). Therefore, the formation of the gettering sink is expected to be conducted immediately before the production process step of the solid imaging device.

### SUMMARY OF THE INVENTION

It is, therefore, an object of the invention to provide a method for producing a wafer for backside illumination type solid imaging device having a plurality of pixels inclusive of a photoelectric conversion device and a charge transfer transistor at its front surface side and a light receiving surface at its back surface side, which is capable of effectively suppressing the occurrence of white defects and heavy metal contamination.

In order to achieve the above object, the summary and construction of the invention are as follows.

(1) A method for producing a wafer for backside illumination type solid imaging device having a plurality of pixels inclusive of a photoelectric conversion device and a charge transfer transistor formed at its front surface side and a light receiving surface at its back surface side, characterized in that an active layer made of a given epitaxial film is formed on a silicon wafer made of a C-containing CZ crystal directly or through an insulating film, and then subjected to a heat treatment to form precipitates containing C and O as a gettering sink at a position just beneath the active layer.

(2) A method for producing a wafer for backside illumination type solid imaging device according to the item (1), wherein the precipitates have a C concentration of 5.0×10¹⁵ to 1.0×10¹⁷ atoms/cm³.

(3) A method for producing a wafer for backside illumination type solid imaging device according to the item (1), wherein the precipitates have an O concentration of 1.0×10¹⁸ to 1.0×10¹⁹ atoms/cm³.

(4) A method for producing a wafer for backside illumination type solid imaging device according to the item (1), wherein the heat treatment is conducted in a mixed gas atmosphere of nitrogen gas and oxygen gas at 600 to 1000° C.

(5) A method for producing a wafer for backside illumination type solid imaging device according to the item (1), wherein the heat treatment is conducted by heating up to 900-1100° C. at a rate of not more than 5° C./min, keeping a state of 900 to 1100° C. for 1-4 hours and then cooling to not higher than 600° C. at a rate of not more than 5° C./min.

According to the invention, it is possible to provide a method for producing a wafer for backside illumination type solid imaging device which is capable of effectively suppressing the occurrence of white defects and heavy metal contamination.

### BRIEF DESCRIPTION OF THE DRAWINGS

The invention will be described with the reference to the accompanying drawings, wherein:

FIG. 1 is a flow chart schematically illustrating production steps of a wafer for backside illumination type solid imaging device according to the invention, wherein (a) shows a silicon wafer, (b) shows a wafer having an active layer formed thereon, and (c) shows a wafer for backside illumination type solid imaging device according to the invention having C and O-containing precipitates formed at a position just beneath the active layer; and

FIG. 2 is a schematically cross-sectional view of a backside illumination type solid imaging device according to the invention.

### DESCRIPTION OF THE PREFERRED EMBODIMENTS

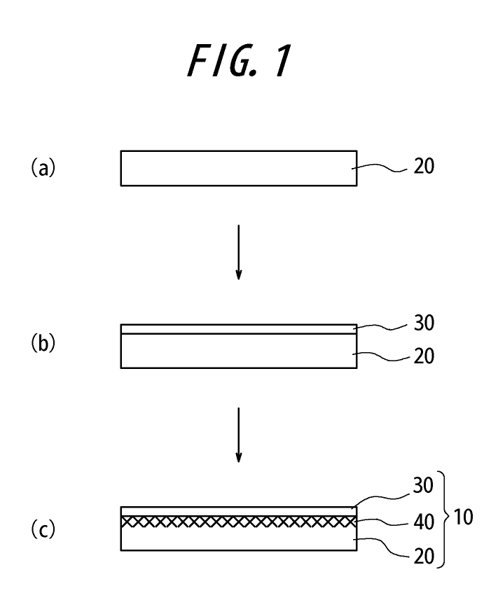

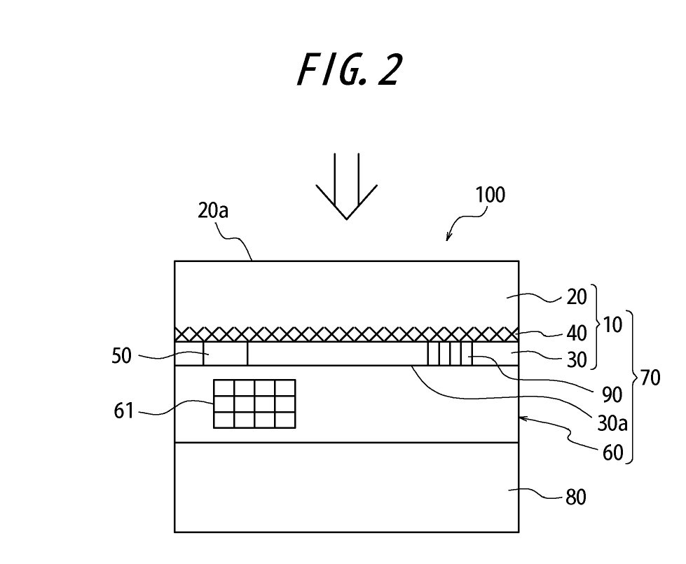

The method for producing a wafer for backside illumination type solid imaging device according to the invention will be described with reference to the drawings. FIGS. 1(a) to (c) are flow charts for explaining the method for producing a wafer for backside illumination type solid imaging device according to the invention. FIG. 2 is a schematically cross-sectional view of a backside illumination type solid imaging device using the wafer for backside illumination type solid imaging device produced by the production steps according to the invention.

The production method according to the invention is a method for producing a wafer for backside illumination type solid imaging device used for a backside illumination type solid imaging device 100 having a plurality of pixels 70 inclusive of a photoelectric conversion device 50 and a charge transfer transistor 60 at its front surface side 30a and a light receiving surface at its back surface side 20a, as shown in FIG. 2.

As shown in FIGS. 1(a) to (c), the method for producing a wafer 10 for backside illumination type solid imaging device 10 is characterized in that an active layer 30 made of a given epitaxial film (FIG. 1(b)) is formed on a silicon wafer 20 made of a C-containing CZ crystal (FIG. 1(a)) directly or through an insulating film (directly in FIG. 1), and then subjected to a heat treatment to form precipitates 40 containing C and O as a gettering sink at a position just beneath the active layer (FIG. 1(c)).

By adopting such a structure can be acted the C and O-containing precipitates 40 formed just beneath the active layer at the heat treatment step in the production of the solid imaging device as a gettering site, so that when the wafer 10 is used in the backside illumination type solid imaging device 100, it is possible to effectively suppress the occurrence of white defects and heavy metal contamination as compared with the conventional imaging device. Also, the deterioration of the gettering ability resulting from the mitigation of crystal defects by subsequent heat treatment (vanishment of precipitates 40) can be prevented since the precipitates 40 are formed after the growth of the epitaxial film 30.

The components in the wafer 10 for backside illumination type solid imaging device according to the invention will be described below.

The silicon wafer 20 according to the invention is required to contain a given amount of C for developing the above gettering effect. Since the other conditions are not particularly limited, the wafer may be n-type wafer or p-type wafer.

Also, the C concentration in the silicon wafer 20 is not particularly limited, but is preferable to be within a range of 1.0×10¹⁶ to 1.0×10¹⁷ atoms/cm³. When the C concentration is less than 1.0×10¹⁶ atoms/cm³, the precipitates 40 acting as a gettering sink as described later can not be formed sufficiently, and hence there is a fear that the occurrence of white defects and heavy metal contamination can not be sufficiently suppressed, while when it exceeds 1.0×10¹⁷ atoms/cm³, the size of the precipitates 40 is less than 50 nm, and hence there is a fear that strain energy capable of gettering heavy metal can not be retained.

Furthermore, when the wafer 10 according to the invention is used in the backside illumination type solid imaging device 100 as shown in FIG. 2, the thickness of the silicon wafer 20 can be processed to not more than 20 μm. The thickness of the support substrate in the wafer used for the conventional backside illumination type solid imaging devices is 40 to 150 μm, whilst since the invention uses a thick film SOI structure, the thickness may be made to not more than 20 μm.

Moreover, the silicon wafer 20 is made of a CZ crystal, because silicon single crystal with few defects can be obtained simply. As a method of including a given amount of C into the silicon wafer 20, there are a method of doping C atoms into a silicon substrate, a method of implanting ions and so on, whereby it is made possible to include the C atoms into the silicon wafer 20.

As shown in FIG. 1(b), the active layer 30 according to the invention is a layer formed on the silicon wafer 20, which is made of a given epitaxial film from a viewpoint that the active layer 30 being less in defects and having a high quality can be obtained relatively easily. Also, the active layer 30 made of the epitaxial film is formed on the silicon wafer 20 directly as shown in FIG. 1(b) or through an insulating film.

The C and O-containing precipitates 40 according to the invention are oxygen precipitates containing C and O formed just beneath the active layer 30 as shown in FIG. 1(c) and serve as a gettering sink. The precipitates 40 can effectively suppress the occurrence of white defects and heavy metal contamination owing to the function as a gettering sink. Further, the inclusion of O atoms can effectively suppress the diffusion of C atoms into the active layer. Moreover, the C and O atoms are inevitably included in the silicon wafer, so that the term “containing C” used herein means the C concentration of not less than 5.0×10¹⁵ atoms/cm³ and the term “containing O” means the O concentration of not less than 1.0×10¹⁷ atoms/cm³.

Also, the C concentration in the precipitates 40 is preferable to be within a range of 5.0×10¹⁵ to 1.0×10¹⁷ atoms/cm³. When the C concentration is less than 5.0×10¹⁵ atoms/cm³, the gettering ability can not be sufficiently developed and there is a fear that the occurrence of white defects and heavy metal contamination can not be sufficiently suppressed, while when it exceeds 1.0×10¹⁷ atoms/cm³, the size of the precipitates 40 is less than 50 nm, and hence there is a fear that strain energy capable of gettering heavy metal can not be retained.

Further, the O concentration in the precipitates 40 is preferable to be within a range of 1.0×10¹⁸ to 1.0×10¹⁹ atoms/cm³. When the 0 concentration is less than 1.0×10¹⁸ atoms/cm³, the promotion of the oxygen precipitation is not sufficient and the gettering ability is deficient, while when it exceeds 1.0×10¹⁹ atoms/cm³, the oxygen precipitation is overmuch, which induces defects.

Moreover, the precipitates 40 are formed by subjecting to a given heat treatment after the active layer 30 made of the epitaxial film is formed on the C-containing silicon wafer 20. In this case, the C atoms contained in the wafer 20 are taken into positions between silicon lattices to promote the precipitation of oxygen-containing substance, resulting in the formation of the precipitates 40 comprising C and O.

In addition, the given heat treatment is preferably conducted in a mixed gas atmosphere of nitrogen gas and oxygen gas at 600 to 1000° C. It is because the oxygen precipitation in the crystal added with carbon is promoted at the above temperature range.

Furthermore, the given heat treatment is preferably conducted by heating up to 900-1100° C. at a rate of not more than 5° C./min, keeping a state of 900 to 1100° C. for 1-4 hours, and then cooling to not higher than 600° C. at a rate of not more than 5° C./min. Since the heating up to 900 to 1100° C. at a rate of not more than 5° C./min is a preferable temperature range for promoting the formation of oxygen precipitating nucleus, if the heating temperature is lower than 900° C., the formation of oxygen precipitating nucleus is suppressed, while if it exceeds 1100° C., only an oxygen precipitating nucleus kept at a critical size grows, and the growth of high-density precipitates is suppressed. Also, the reason why the high temperature state (900 to 1100° C.) is kept for 1 to 4 hours is due to the fact that when the keeping time is less than 1 hour, the growth of oxygen precipitating nucleus is not sufficient, while when it exceeds 4 hours, the excessive growth of oxygen precipitating nucleus is feared. Moreover, the reason of cooling to not higher than 600° C. at a rate of not more than 5° C./min is due to the fact that when the temperature exceeds 600° C., it is feared to cause the excessive growth of the oxygen precipitates.

Moreover, as shown in FIG. 2, the backside illumination type solid imaging device 100 can be prepared when a buried electrode (not shown) for transferring image data is connected to the pixels 70 including the wafer 10 for backside illumination type solid imaging device 10 produced by the production method of the invention. By the gettering effect of the wafer 10 for backside illumination type solid imaging device 10 according to the invention, it is made possible to provide the backside illumination type solid imaging device 100 being excellent in the ability of suppressing the occurrence of white defects and heavy metal contamination as compared with the conventional backside illumination type solid imaging device. In FIG. 2, a buried wiring 61 is disposed in the charge transfer transistor 60 and further a substrate 80 is arranged as a base for the pixels 70.

Although the above is described with respect to only one embodiment of the invention, various modifications may be made without departing from the scope of the appended claims.

A wafer for backside illumination type solid imaging device according to the invention is prepared as a sample and its performances are evaluated as described below.

### EXAMPLE 1

As shown in FIG. 1, an epitaxial film of Si is formed on a silicon wafer 20 made of C-containing n-type silicon (C concentration: 1.0×10¹⁶ atoms/cm³, specific resistance: 10 Ω·cm) (FIG. 1(a)) through a CVD method as an active layer 30 (FIG. 1(b)). Thereafter, the silicon wafer 20 provided with the active layer 30 is heated in a mixed gas atmosphere of nitrogen and oxygen from 900 to 1000° C. at a rate of not more than 5° C./min, kept at this temperature for 4 hours and then cooled to 600° C. at a rate of not more than 5° C./min, whereby precipitates 40 having a C concentration of 3.0×10¹⁶ atoms/cm³ and an O concentration of 1.4×10¹⁸ atoms/cm³ are formed at a position just beneath the active layer 30 (a depth position of about 0.10 μm from the active layer) (FIG. 1(c)) to obtain a wafer 10 for solid imaging device as a sample.

### COMPARATIVE EXAMPLE 1

A sample of a wafer 10 for backside illumination type solid imaging device is obtained at the same steps as in Example 1 except that an epitaxial film of Si is formed as an active layer 30 on a silicon wafer 20 (not containing C) (FIG. 1(a)) through a CVD method

### COMPARATIVE EXAMPLE 2

A sample of a wafer 10 for backside illumination type solid imaging device is obtained under the same conditions as in Example 1 except that a silicon wafer 20 provided with an active layer 30 is heated in a nitrogen gas atmosphere up to 1000° C. at a rate of not more than 5° C./min, kept at this temperature for 4 hours and then cooled to 600° C. at a rate of 5° C./min to make a wafer 10 having a C concentration of 1.0×10¹⁵ atoms/cm³ and an O concentration of 5.0×10¹⁶ atoms/cm³ (C and O-containing precipitates according to the invention are not formed).

(Evaluation Method)

Each sample prepared in the above example and comparative examples is evaluated by the following evaluation methods.

(1) White Defects

A backside illumination type solid imaging device is prepared by using each sample prepared in the above example and comparative examples, and thereafter a dark leakage current of a photodiode in the backside illumination type solid imaging device is measured and converted to pixel data (data of white defect number) with a semiconductor parameter analyzing apparatus, whereby the number of white defects per unit area (cm²) is counted to evaluate the suppression on the occurrence of white defects. The evaluation standard is shown below, and the measured results and evaluation results are shown in Table 1.
⊚: not more than 5
◯: more than 5 but not more than 50
X: more than 50

(2) Heavy Metal Contamination

A defect density (defect number/cm²) on the surface of the sample is measured by contaminating the sample surface with nickel (1.0×10¹² atoms/cm²) by a spin coat contamination method and thereafter subjecting to a heat treatment at 900° C. for 1 hour and then selectively etching the surface of the sample. The evaluation standard is shown below, and the measured results and evaluation results are shown in Table 1.
⊚: less than 5/cm²
◯: not less than 5 but less than 50/cm²
X: not less than 50/cm²

TABLE 1

| | Precipitates | | | |
|---|---|---|---|---|
| | containing C and O | | Evaluation results | |
| | C content | O content | White | Heavy metal |
| | (atoms/cm³) | (atoms/cm³) | defects | contamination |
| Example 1 | 1.0 × 10¹⁶ | 1.0 × 10¹⁸ | ◯ | ◯ |
| Comparative | 5.0 × 10¹⁵ | 8.0 × 10¹⁷ | X | X |
| Example 1 | | | | |
| Comparative | 1.0 × 10¹⁵ | 5.0 × 10¹⁶ | X | X |
| Example 2 | | | | |

As seen from the results of Table 1, Example 1 can suppress the occurrence of white defects and heavy metal contamination and has a high gettering ability as compared with Comparative Examples 1 and 2.

According to the invention, it is possible to provide a wafer for backside illumination type solid imaging device capable of effectively suppressing occurrence of white defects and heavy metal contamination, and also it is made possible by the gettering effect of the wafer to provide a backside illumination type solid imaging device being excellent in the ability of suppressing the occurrence of white defects and heavy metal contamination as compared with the conventional backside illumination type solid imaging device.

What is claimed is:

1. A method for producing a wafer for backside illumination type solid imaging device having a plurality of pixels inclusive of a photoelectric conversion device and a charge transfer transistor formed at its front surface side and a light receiving surface at its back surface side, characterized in that an active layer made of a given epitaxial film is formed on a silicon wafer made of a C-containing CZ crystal directly or through an insulating film, and then subjected to a heat treatment to form precipitates containing C and O as a gettering sink at a position just beneath the active layer.

2. A method for producing a wafer for backside illumination type solid imaging device according to claim 1, wherein the precipitates have a C concentration of 5.0×10¹⁵ to 1.0×10¹⁷ atoms/cm³.

3. A method for producing a wafer for backside illumination type solid imaging device according to claim 1, wherein the precipitates have an O concentration of 1.0×10⁸ to 1.0×10¹⁹/atoms cm.

4. A method for producing a wafer for backside illumination type solid imaging device according to claim 1, wherein the heat treatment is conducted in a mixed gas atmosphere of nitrogen gas and oxygen gas at 600 to 1000° C.

5. A method for producing a wafer for backside illumination type solid imaging device according to claim 1, wherein the heat treatment is conducted by heating up to 900 to 1000° C. at a rate of not more than 5° C./min, keeping a state of 900 to 1100° C. for 1-4 hours, and then cooling to not higher than 600° C. at a rate of not more than 5° C./min.
